(19) United States
(12) Patent Application Publication
(10) Pub. No.: US 2019/0146908 A1
(43) Pub. Date: May 16, 2019

(54) METHOD FOR ACCESSING FLASH MEMORY MODULE AND ASSOCIATED FLASH MEMORY CONTROLLER AND ELECTRONIC DEVICE

(71) Applicant: Silicon Motion Inc., Hsinchu County (TW)

(72) Inventors: Chang-Chieh Huang, Hsinchu County (TW); Chen-Yin Lin, Taipei City (TW)

(21) Appl. No.: 15/865,271

(22) Filed: Jan. 9, 2018

(30) Foreign Application Priority Data
Nov. 13, 2017 (TW) 106139113

(51) Int. Cl. G06F 12/02; G11C 16/10; G11C 16/26; G06F 3/06

(52) U.S. Cl. CPC G06F 12/0246; G06F 12/0292; G11C 16/10; G06F 2212/2022; G06F 3/064; G06F 3/0679; G06F 2212/7201; G11C 16/26

(57) ABSTRACT

The present invention provides a method for accessing a flash memory module, wherein the method comprises: building a physical address to logical address (P2L) table; building a logical address group table, wherein the logical address group table records statuses of a plurality of logical address groups; receiving a read command asking for a data within the flash memory module, wherein the read command comprises a specific logical address; referring to a status of a specific logical address group corresponding the specific logical address to determine if searching the P2L mapping table or not, to obtain a specific physical address corresponding to the specific logical address, wherein the specific physical address is utilized to read the data from the flash memory module.

### BACKGROUND OF THE INVENTION

1. Field of the Invention

The present invention relates to a flash memory, and more particularly, to a method for accessing a flash memory module and related flash memory module.

### 2. Description of the Prior Art

During the operation of the flash memory controller, a physical address to logical address mapping table (P2L) or at least a logical address to physical address (L2P) mapping table is usually stored in the buffer memory of the flash memory controller. When the flash memory controller receives a read command, it can search the above L2P mapping table for the required physical addresses. However, as the size of the blocks increases and the number of data pages in the blocks also increases, the size of the mapping table also increases drastically, so the time required to find the required physical address will also increase a lot, and the performance of the flash memory controller is affected.

### SUMMARY OF THE INVENTION

Therefore, an object of the present invention is to provide a method for accessing a flash memory module, which can efficiently search a required physical address when a flash memory controller receives a read command, so as to improve the flash memory controller performance.

According to a first aspect of the present invention, an exemplary method for accessing a flash memory module is disclosed. The method comprises: building a physical address to logical address (P2L) table, which comprises consecutive physical addresses and corresponding logical addresses of the consecutive physical addresses; building a logical address group table, wherein the logical address group table records the statuses of a plurality of logical address groups, wherein the status of each logical address group is utilized to represent whether there is any logical address of the logical address group recorded in the P2L mapping table; receiving a read command asking for a data within the flash memory module, wherein the read command comprises a specific logical address; and referring to a status of a specific logical address group corresponding the specific logical address to determine if searching the P2L mapping table or not, to obtain a specific physical address corresponding to the specific logical address, wherein the specific physical address is utilized to read the data from the flash memory module.

According to a second aspect of the present invention, an exemplary flash memory controller is disclosed, wherein the flash memory controller is utilized to access a flash memory module. The flash memory controller comprises: a read-only memory (ROM), a microprocessor, and a memory. The ROM is utilized for storing a code. The microprocessor is utilized for executing the code to control access to the flash memory module. The memory is utilized for storing a P2L mapping table and a logical address group table, wherein the P2L mapping table comprises consecutive physical addresses and corresponding logic addresses of the consecutive physical addresses, and the logical address group table records the statuses of a plurality of logical address groups, wherein the status of each logical address group is utilized to represent whether there is any logical address of the logical address group recorded in the P2L mapping table; wherein when the microprocessor receives a read command asking for a data within the flash memory module, the microprocessor refers to a status of a specific logical address group corresponding the specific logical address to determine if searching the P2L mapping table or not, to obtain a specific physical address corresponding to the specific logical address, wherein the specific physical address is utilized to read the data from the flash memory module.

According to a third aspect of the present invention, an exemplary electronic device is disclosed. The electronic device comprises: a flash memory module and a flash memory controller. The flash memory controller is utilized for accessing the flash memory module, and building a P2L mapping table and a logical address group recording table, wherein the P2L mapping table comprises consecutive physical addresses and corresponding logical addresses of the consecutive physical addresses, and the logical address group tablerecords the statuses of a plurality of logical address groups, wherein the status of each logical address group is utilized to represent whether there is any logical address of the logical address group recorded in the P2L mapping table; wherein when the flash memory controller receives a read command asking for a data within the flash memory module, the flash memory controller refers to a status of a specific logical address group corresponding the specific logical address to determine if searching the P2L mapping table or not, to obtain a specific physical address corresponding to the specific logical address, wherein the specific physical address is utilized to read the data from the flash memory module.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a memory device according to an embodiment of the present invention.

FIG. 2 is a flowchart of accessing a flash memory module according to an embodiment of the present invention.

FIG. 3 is a schematic diagram of a P2L mapping table.

FIG. 4 is a schematic diagram of a logical address group table.

FIG. 5 is a schematic diagram of L2P mapping tables.

FIG. 6 is a flowchart of accessing a flash memory module 120 according to another embodiment of the present invention.

FIG. 7 is a schematic diagram of updating the L2P mapping table by using the P2L mapping table according to an embodiment of the present invention.

### DETAILED DESCRIPTION

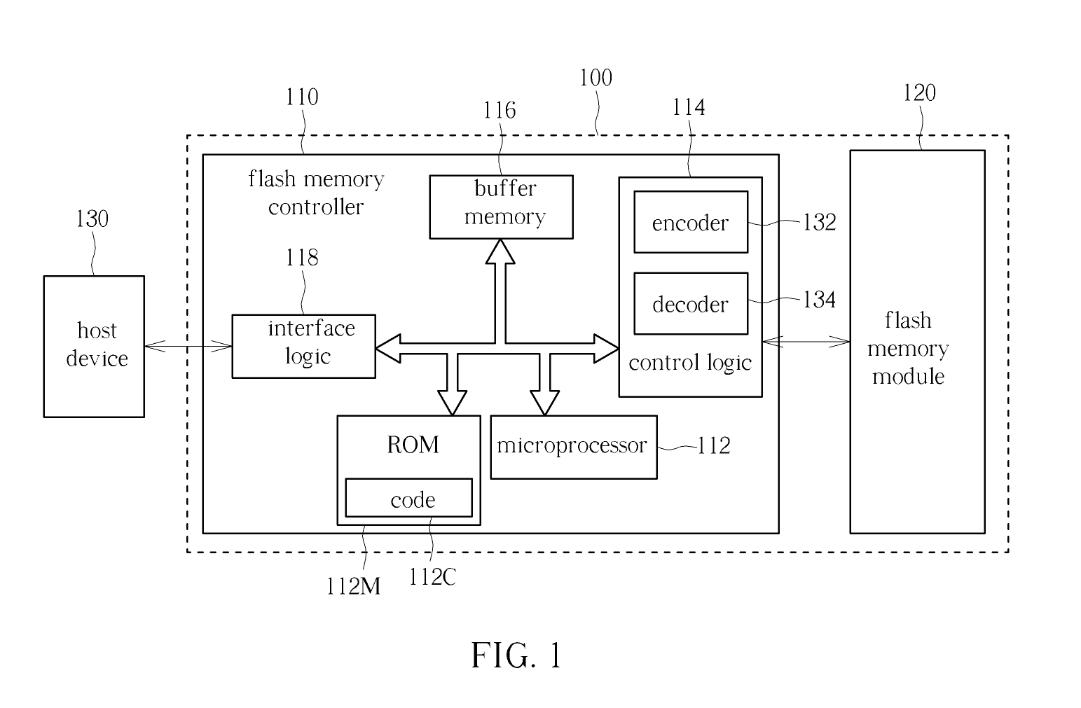

Please refer to FIG. 1. FIG. 1 is a diagram illustrating a memory device 100 according to an embodiment of the present invention. The memory device 100 comprises a flash memory module 120 and a flash memory controller 110, and the flash memory controller 110 is utilized to access the flash memory module 120. According to this embodiment, the flash memory controller 110 comprises a microprocessor 112, a read only memory (ROM) 112M, a control logic 114, a buffer memory 116, and an interface logic 118. The read-only memory 112M is utilized to store a program code 112C, and the microprocessor 112 is utilized to execute program code 112C to control access to the flash memory module 120. The control logic 114 comprises an encoder 132 and a decoder 134. The encoder 132 is configured to encode data written into the flash memory module 120 to generate a corresponding check code (or error correction (Error Correction Code, ECC), and the decoder 134 is utilized to decode the data read from the flash memory module 120.

In a typical situation, the flash memory module 120 comprises a plurality of flash memory chips, and each flash memory chip comprises a plurality of blocks, and the data erasing operation for the flash memory module 120 by the controller (e.g., the flash memory controller 110 executing the code 112C via the microprocessor 112) is performed in units of blocks. In addition, a block can record a specific number of data pages (data pages) in which the data writing operation for the flash memory module 120 by the controller (e.g., the flash memory controller 110 executing the code 112C via the microprocessor 112) is performed to write in units of data pages. In this embodiment, the flash memory module 120 is a three-dimensional NAND type flash memory (3D NAND-type flash).

In practice, the flash memory controller 110 executing the code 112C via the microprocessor 112, can perform a number of control operations by using its own internal components, such as controlling the flash memory module 120 by using the control logic 114 (especially the access operations for at least one block or at least one data page), buffering the required buffering operations by using the buffer memory 116, and using the interface logic 118 to communicate with a host device 130. The buffer memory 116 is implemented in a random access memory (RAM). For example, the buffer memory 116 can be a static random access memory (SRAM), but the present invention is not limited thereto.

In an embodiment, the memory device 100 can be a portable memory device (e.g., a memory card that complies with to the SD/MMC, CF, MS, XD standard), and the host device 130 can be an electronic device capable of connecting to the memory device, such as cell phones, laptops, desktops, etc. In another embodiment, the memory device 100 can be a solid-status hard disk or an embedded storage that complies with Universal Flash Storage (UFS) or Embedded Multi Media Card (EMMC) specification, which is provided in an electronic device, such as in a mobile phone, a notebook computer, a desktop computer, and the host device 130 can be a processor of the electronic device.

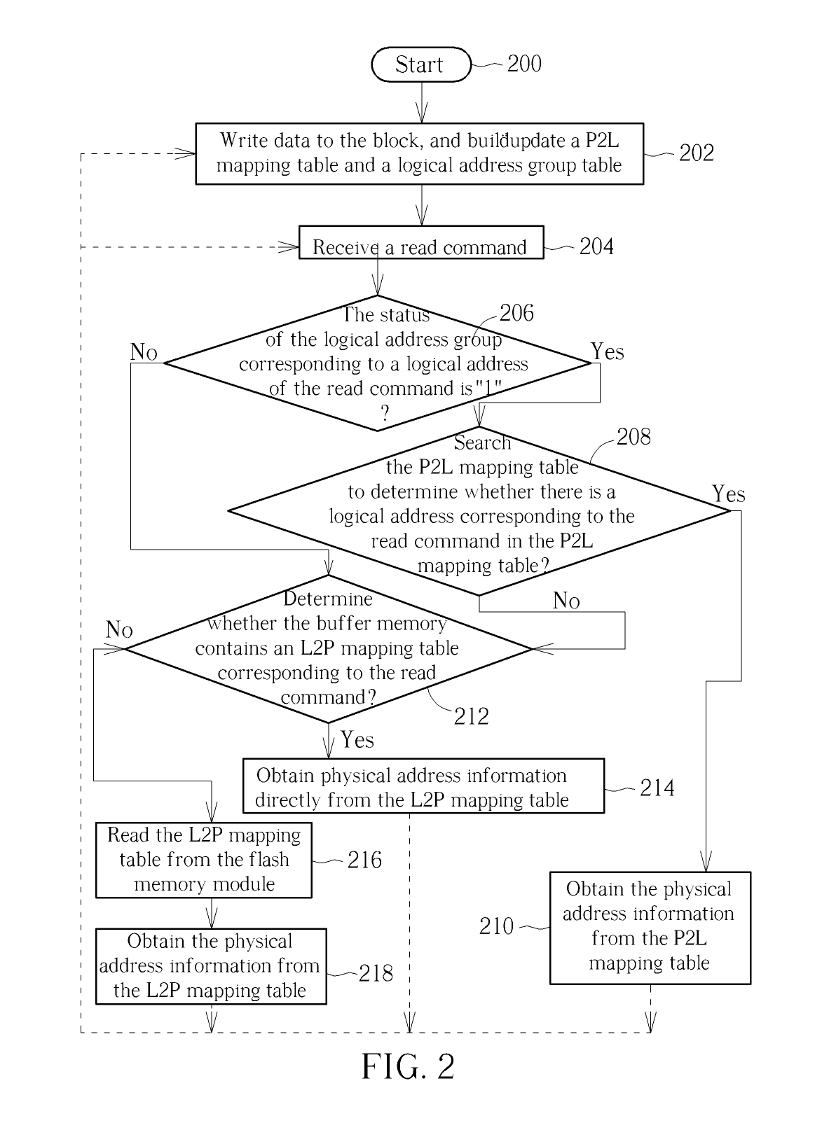

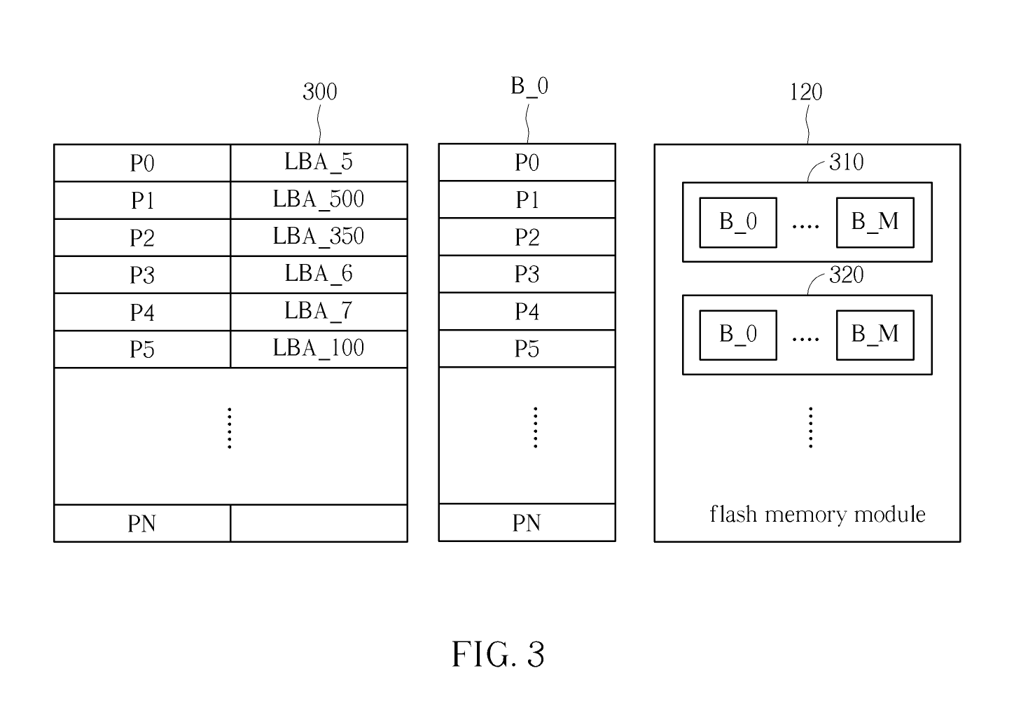

Please refer to FIG. 2. FIG. 2 is a flow chart of accessing the flash memory module 120 according to an embodiment of the present invention. In the step 200, the flow starts. In the step 202, the flash memory controller 110 receives at least a write command from the host device 130 to write multiple data into a block of the flash memory module 120. In this embodiment, referring to FIG. 3, the flash memory module 120 comprises a plurality of flash memory chips 310, 320, each of which comprises a plurality of blocks B_0˜B_M, and each block comprises N data pages P0˜PN. In the following description, the flash memory controller 110 sequentially writes the data to the block B_0 of the flash memory chip 410. However, it should be noted that the above-mentioned “block” also can be a plurality of blocks (generally referred to as “super blocks”) located in different planes and comprising multiple chips. For example, assuming that the flash memory chips 310, 320 comprise two planes, and the blocks B_0 and B_M are located on different planes, then the blocks B_0, B_M of the flash memory chip 310 and the blocks B_0, B_M of the flash memory chip 320 can constitute a super block.

Before the data is written to the block B_0, the microprocessor 112 creates a physical address to a logical address mapping table (hereinafter referred to as a P2L mapping table) 300 and stores it in the buffer memory 116, wherein the P2L mapping table 300 comprises physical addresses of the consecutive data pages P0˜PN in the block B_0 and the corresponding logical addresses. In detail, the flash memory controller 110 first writes the data from the host device 130 and having the logical address LBA_5 into the data page P0, and then sequentially writes the data from the host device 130 with the logical addresses LBA_500, LBA_350, LBA_6, LBA_7, LBA_100 to the data pages P1 to P5, respectively. In addition, the microprocessor 112 can save the P2L mapping table 300 to the flash memory module 120 after all the data pages P0˜PN of the block B_0 have been written. It is to be noted that in this embodiment, the ordinal number of the physical address represents its order, and the consecutive sequence numbers represent the consecutive physical addresses.

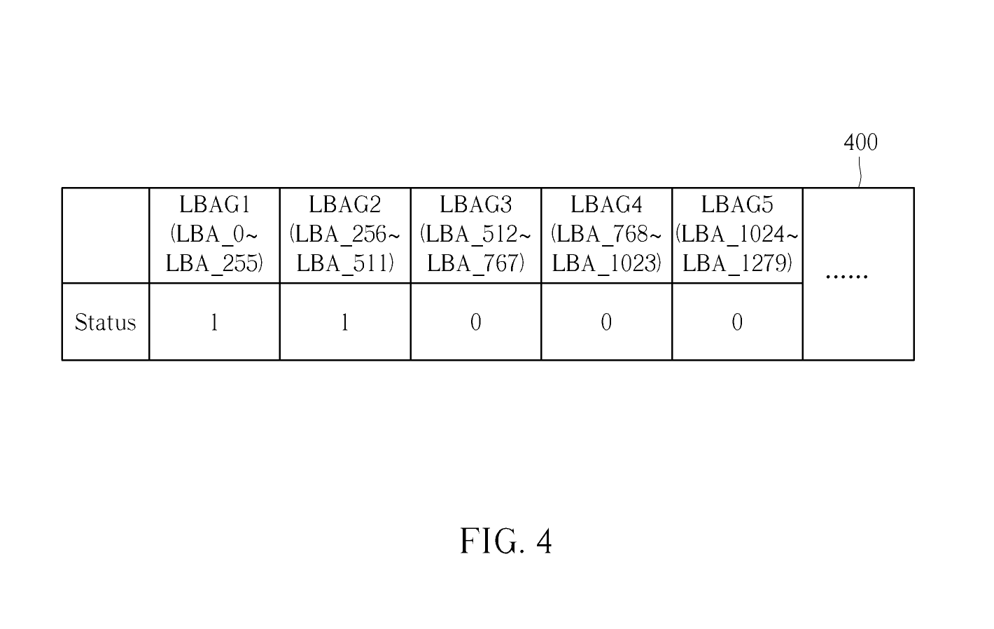

On the other hand, the microprocessor 112 additionally records a logical address group table 400 as shown in FIG. 4 and stores it in the buffer memory 116. The logical address group table 400 records the statuses of a plurality of logical address groups, wherein the status of each logical address group is utilized to represent whether there is any logical address of the logical address group recorded in the P2L mapping table 300. In this embodiment, referring to FIG. 4, the logical address group table 400 comprises at least a plurality of logical address groups LBAG1˜LBAG5, and each logical address group comprises a logical address range. For example, the logical address group LBAG1 comprises the logical addresses LBA_0˜LBA_255; the logical address group LBAG2 comprises the logical addresses LBA_256˜LBA_511; the logical address group LBAG3 comprises the logical addresses LBA_512˜LBA_767; the logical address group The group LBAG4 comprises logical addresses LBA_768˜LBA_1023; and the logical address group LBAG5 comprises logical addresses LBA_1024˜LBA_1279. In addition, the logical address group table 400 utilizes a bit to represent the status of each logical address group. For example, since the P2L mapping table records LBA_5˜LBA_7, LBA_100, LBA_350, and LBA_500, the status of the logical address groups LBAG1 and LBAG2 is set to a digital value of “1”. Since the P2L mapping table does not comprise the logical address LBA_512˜LBA_1279, the status of the logical address groups LBAG3˜LBAG5 is set to a digital value “0”.

It should be noted that the logical address group table 400 shown in FIG. 4 is only an example and not intended to be a limitation of the present invention. As long as the logical address group table 400 can be utilized to indicate whether any logical address in the logical address group is recorded in the P2L mapping table 300, the details of the contents can vary accordingly, and various modifications and alterations of the design should fall into the disclosed scope of the present invention.

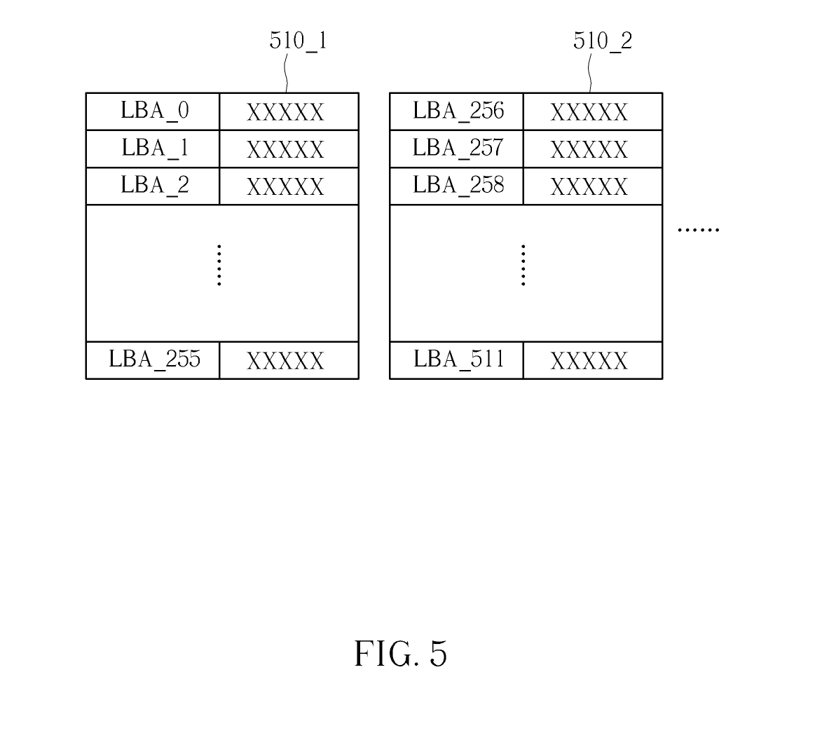

In addition, in this embodiment, the logical address range of each of the logical address groups LBAG1˜LBAG5 is the same as the logical address range of a logical address to physical address mapping table (hereinafter referred to as an L2P mapping table) utilized in the memory device 100. For example, please refer to FIG. 5. FIG. 5 is a schematic diagram of a plurality of L2P mapping tables, wherein each L2P mapping table, for example, illustrated as 510_1 and 510_2, comprises consecutive logical addresses and corresponding physical addresses.

In the step 204, the flash memory controller 110 receives a read command from the host device 130 to request that the data with a specific logical address be read from the flash memory module 120. Next, in the step 206, the microprocessor 112 determines whether the status of a logical address group corresponding to the specific logical address is the digital value “1”. If yes, the flow goes to the step 208; otherwise, the flow goes to the step 212. For example, assuming that the specific logical address is LBA_30, the flow will proceed to the step 208 since LBA_30 is located in logical address group LBAG1 with the status “1”; and assuming that the specific logical address is LBA_700, the flow will proceed to the step 212 since LBA_700 is located in the logical address group LBAG3 with the status “0”.

In the step 208, the microprocessor 112 searches the P2L mapping table 300 and determines whether the specific logical address is located in the P2L mapping table 300. If yes, the flow goes to the step 210; otherwise, the flow goes to the step 212. In the step 210, the microprocessor 112 can directly search the P2L mapping table 300 stored in the buffer memory 116 for the physical address corresponding to the specific logical address, and find the data stored in the physical address from the flash memory module 120 according to the searched physical address

In the step 212, since the status of the logical address group correspond to the specific logical address is “0”, it means that no information about the specific logical address is stored in the P2L mapping table 300 (that is, the area Block B_0 does not comprise the data with the specific logical address). Therefore, the microprocessor 112 does not need to perform an operation of searching the P2L mapping table 300, but directly determines whether the buffer memory 116 has an L2P mapping table comprising the specific logical address. For example, assuming that the specific logical address is LBA_700, the microprocessor 112 determines whether an L2P mapping table with LBA_512˜LBA_767 is stored in the buffer memory 116; if yes, the flow goes to the step 214; otherwise, the flow goes to the step 216.

In the step 214, since the buffer memory 116 stores the L2P mapping table having the related information of LBA_512˜LBA_767, the microprocessor 112 can directly read the physical address corresponding to the searched specific logical address LBA_700 from the L2P mapping table, and read the data stored in the physical address from the flash memory module 120 according to the searched physical address.

In the step 216, since the buffer memory 116 does not have an L2P mapping table of LBA_512˜LBA_767 related information, the microprocessor 112 reads the L2P mapping table with the information related to LBA_512˜LBA_767 from the flash memory module 120 and store it into the buffer memory 116. Next, in the step 218, the microprocessor 112 reads the physical address corresponding to the searched specific logical address LBA_700 from the loaded L2P mapping table, and read the data stored in the physical address from the flash memory module 120 according to the searched physical address.

The subsequent flow can return to the step 202 to continue writing data to block B_0 and synchronously build/update the P2L mapping table 300 and the logical address group table 400, or proceed to the step 204 to receive the next read command. In addition, if the flash memory controller 110 continues to write data to the block B_0, the written data may have been updated data of the previously written data (i.e. has the same logical address). In order to avoid subsequent searching errors, once there is data written into the block B_0, one or more L2P mapping tables previously loaded due to the read command will be invalidated, that is, the L2P mapping table in the buffer memory 116 will be marked as invalid or deleted.

With reference to the above embodiment, when the microprocessor 112 receives the read command, it directly refers to the logical address group table 400 stored in the buffer memory 116 to determine whether the logical address contained in the read command is possible to be contained in the P2L mapping table 300. If the logical address group table 400 indicates that the logical address contained in the read command does not exist in the P2L mapping table 300, the microprocessor 112 does not need to search the P2L mapping table 300, and can obtain the required physical address directly from the L2P mapping table of the buffer memory 116 or from the L2P mapping table loaded in the flash memory module 120. Therefore, the embodiment of the present invention can reduce the number of times of invalid reading of the P2L mapping table, so that the reading speed of the flash memory controller can be accelerated and the system performance can be improved. On the other hand, since the logical address group table 400 requires only a small amount of memory space, it does not have a substantial effect on the buffer memory 116.

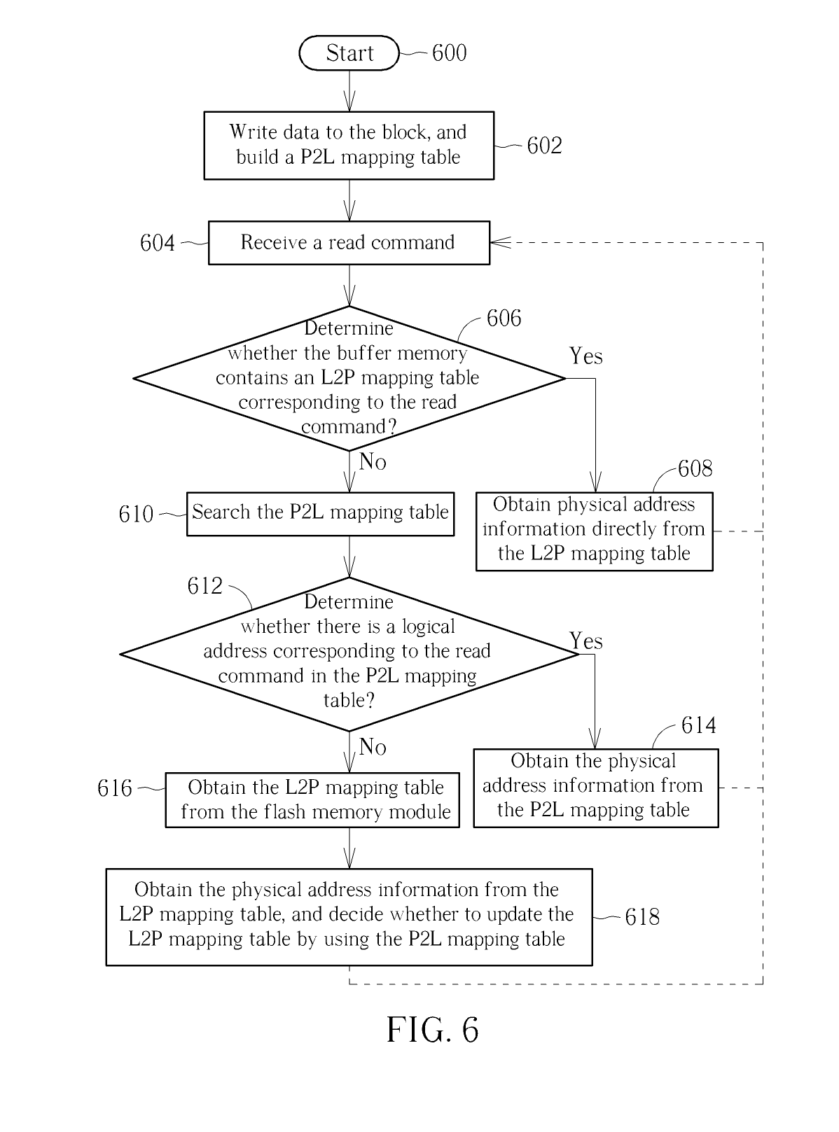

In addition, in the above embodiment, the logical address group table 400 is utilized in the case where the flash memory controller 110 receives the read command. However, in other embodiments, the logical address group table 400 can also be utilized in any other operations that require searching the P2L mapping table 300. For example, in some cases, since the P2L mapping table 300 has the latest information, the microprocessor 112 will need to utilize the P2L mapping table 300 to update a plurality of L2P mapping tables loaded from the flash memory module 120 (For example, 510_1 and 510_2 in FIG. 5). At this time, the microprocessor 112 can refer to the logical address group table 400 to determine which L2P mapping tables are to be updated (those not recorded in the logical address group table 400 are not required to be processed) to avoid invalid update operations. Specifically, please refer to FIG. 6, which is a flowchart of accessing a flash memory module 120 according to another embodiment of the present invention. In the step 600, the process starts. In the step 602, the flash memory controller 110 receives at least a write command from the host device 130 to write multiple data into a block of the flash memory module 120. In the following description, the flash memory controller 110 sequentially writes data to the block B_0 of the flash memory chip 310 shown in FIG. 3.

On the other hand, before the data is written into the block B_0, the microprocessor 112 will build a P2L mapping table, such as the P2L mapping table 300 shown in FIG. 3, and store it in the buffer memory 116. The microprocessor 112 additionally records the logical address group table 400 shown in FIG. 4 and stores it in the buffer memory 116.

In the step 604, the flash memory controller 110 receives a first read command from the host device 130 to read data with the first logical address from the flash memory module 120. Next, in the step 606, the microprocessor 112 determines whether an L2P mapping table comprising the first logical address is stored in the buffer memory 116. Specifically, the flash memory module 120 stores a plurality of L2P mapping tables, and each L2P mapping table comprises mapping information of a logical address range. For example, a first L2P mapping table is utilized to store the physical addresses corresponding to LBA_0˜LBA_255 (please note that not every physical address corresponding to the physical address exists); the second L2P mapping table is utilized to store the physical addresses corresponding to LBA_256˜LBA_511; a third L2P mapping table is utilized to store the physical address corresponding to LBA_512˜LBA_767, and so on. Therefore, in the above example, if the first logical address is LBA_20, the microprocessor 112 determines whether the first L2P mapping table utilized to store LBA_0˜LBA_255 is located in the buffer memory 116. If yes, the flow goes to the step 608; otherwise, the flow goes to the step 610. The following paragraphs describe the first logical address as LBA_20 for illustration.

In the step 608, if the first L2P mapping table is stored in the buffer memory 116, the microprocessor 112 can directly search the physical address corresponding to the first logical address LBA_20 from the first L2P mapping table stored in the buffer memory 116, and find the data stored in the physical address from the flash memory module 120 according to the searched physical address.

In the step 610, the microprocessor 112 searches the P2L mapping table 300 and determines whether the first logical address LBA_20 is located in the P2L mapping table 300. If yes, the flow goes to the step 214; otherwise, the flow goes to the step 216.

In the step 614, the microprocessor 112 can directly search the physical address corresponding to the first logical address LBA_20 from the P2L mapping table 300 stored in the buffer memory 116, and find the data stored in the physical address from the flash memory module 120 according to the searched physical address.

In the step 616, since the relevant information of the first logical address LBA_20 is not stored in the buffer memory 116, the microprocessor 112 reads the first L2P mapping table comprising the first logical address LBA_20 from the flash memory module 120 according to the first logical address LBA_20. In this embodiment, the microprocessor 112 reads the first L2P mapping table utilized to store the LBA_0˜LBA_255 from the flash memory module 120 and stores the L2P mapping table into the buffer memory 116.

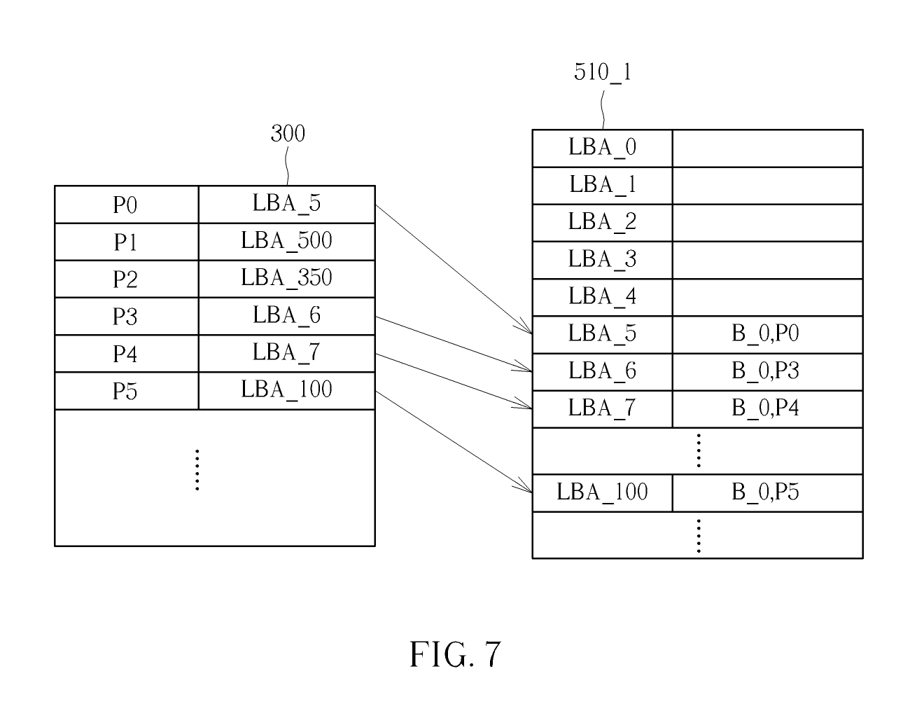

In the step 618, the microprocessor 112 reads the physical address corresponding to the first logical address LBA_20 from the read first L2P mapping table and reads the data stored in the physical address from the flash memory module 120 according to the searched physical address. In addition, at this moment, the microprocessor 116 will refer to the logical address group table 400 to decide whether to update the first L2P mapping table by using the P2L mapping table 300, so that the first L2P mapping table stores the latest information Specifically, since the status of the logical address group LBAG1 recorded in the logical address group table 400 is set to the digital value “1”, the microprocessor 116 can be directly update the first L2P mapping table (for example, 510_1 shown in FIG. 5) by using the P2L mapping table 300. Please refer to FIG. 7, which is a schematic diagram of updating the L2P mapping table 510_1 by using the P2L mapping table 300. In FIG. 7, since there are four pieces of information corresponding to the logical address range LBA_0˜LBA_255 in the P2L mapping tables 300, the microprocessor 112 updates the logical address LBA_5 in the L2P mapping table 510_1 to correspond to the data page P0 of the block B0, the logical address LBA_6 to correspond to the data page P3 of the block B_0, the logical address LBA_7 to correspond to the data page P4 of the block B_0, and the logical address LBA_100 to correspond to the data page P5 of the block B_0.

It should be noted that before the L2P mapping table 510_1 is read from the flash memory module 120 but has not been updated, the L2P mapping table 510_1 is able to not comprise the corresponding physical addresses of the logical address LBA_5, LBA_6, LBA_7, or LBA_100. At this time, the microprocessor adds the above four pieces of information in the P2L mapping table 300 to the L2P mapping table 510_1. Or, the L2P mapping table 510_1 already comprises the corresponding physical addresses of the logical address LBA_5, LBA_6, LBA_7, or LBA_100, and at this time, the microprocessor uses the four pieces of information in the P2L mapping table 300 to update the physical address corresponding to the logical address LBA_5, LBA_6, LBA_7 or LBA_100 in the L2P mapping table 510_1.

In another example, it is assumed that the flow again returns to the step 604, and the flash memory controller 110 receives a second read command from the host device 130 to read data with the first logical address from the flash memory module 120. Assuming that the second logical address is LBA_800, since the logical address LBA_800 is not comprised in the P2L mapping table 300, the flow proceeds to the step 616 to read the L2P mapping table comprising the second logical address LBA_800 from the flash memory module 120, for example, a fourth L2P mapping table for storing LBA_768˜LBA_1023, and store the L2P mapping table in the buffer memory 116. Next, the microprocessor 112 searches the physical address corresponding to the second logical address LBA_800 in the fourth L2P mapping table, and reads the data stored in the physical address from the flash memory module 120 according to the searched physical address. In addition, at this time, the microprocessor 116 will refer to the logical address group table 400 to decide whether to update the fourth L2P mapping table by using the P2L mapping table 300. Specifically, since the status of the logical address group LBAG4 recorded in the logical address group table 400 is set to the digital value “0”, the microprocessor 116 does not need to utilize the P2L mapping table 300 to update the fourth L2P mapping table, so as to avoid invalid update operations.

Those skilled in the art will readily observe that numerous modifications and alterations of the device and method can be made while retaining the teachings of the invention. Accordingly, the above disclosure should be construed as limited only by the metes and bounds of the appended claims.

What is claimed is:

1. A method for accessing a flash memory module, comprising:
building a physical address to logical address (P2L) table, which comprises consecutive physical addresses and corresponding logical addresses of the consecutive physical addresses;
building a logical address group table, wherein the logical address group table records the statuses of a plurality of logical address groups, wherein the status of each logical address group is utilized to represent whether there is any logical address of the logical address group recorded in the P2L mapping table;
receiving a read command asking for a data within the flash memory module, wherein the read command comprises a specific logical address; and
referring to a status of a specific logical address group corresponding the specific logical address to determine if searching the P2L mapping table or not, to obtain a specific physical address corresponding to the specific logical address, wherein the specific physical address is utilized to read the data from the flash memory module.

2. The method of claim 1, wherein the logical address group table utilizes a bit to represent the status of the logical address group, wherein the two digit values of the bit are utilized to represent whether there is any logical address of the logical address group recorded in the P2L mapping table.

3. The method of claim 1, wherein each of the logical address groups comprises a logical address range and the logical address range is the same as a range of a logical address to physical address (L2P) table utilized by the flash memory module.

4. The method of claim 1, wherein the step of referring to the status of the specific logical address group corresponding the specific logical address to determine if searching the P2L mapping table or not comprises:
when the status of the specific logical address group indicates that any one of the logical addresses in the logical address group is recorded in the P2L mapping table, directly searching the P2L mapping table to determine whether information related to the specific logical address is contained; and
when the status of the specific logical address group indicates that no logical address in the logical address group is recorded in the P2L mapping table, obtaining a specific physical address corresponding to the specific logical address form a L2P mapping table without searching the P2L mapping table, to read the data from the flash memory module.

5. The method of claim 4, wherein in the case of not searching the P2L mapping table, the step of obtaining the specific physical address corresponding to the specific logical address form the L2P mapping table comprises:
reading the logical address from the flash memory module to the L2P mapping table, and searching the specific physical address from the L2P mapping table.

6. The method of claim 5, wherein in the case of not searching the P2L mapping table, the step of obtaining the specific physical address corresponding to the specific logical address form the L2P mapping table comprises:
determining whether a buffer memory of a flash memory controller stores the L2P mapping table;
when the buffer memory has the L2P mapping table, searching for the specific physical address directly from the L2P mapping table stored in the buffer memory; and
when the buffer memory does not have the L2P mapping table, reading the L2P mapping table from the flash memory module, and searching for the specific physical address from the L2P mapping table.

7. The method of claim 1, further comprising:
reading at least a L2P mapping table from the flash memory module;
determining whether to utilize the P2L mapping table to update the L2P mapping table according to the logical address group table.

8. A flash memory controller, wherein the flash memory controller is utilized to access a flash memory module, and the flash memory controller comprises:
a read-only memory (ROM), for storing a code;
a microprocessor, for executing the code to control access to the flash memory module; and
a memory, for storing a P2L mapping table and a logical address group table, wherein the P2L mapping table comprises consecutive physical addresses and corresponding logic addresses of the consecutive physical addresses, and the logical address group table records the statuses of a plurality of logical address groups, wherein the status of each logical address group is utilized to represent whether there is any logical address of the logical address group recorded in the P2L mapping table;
wherein when the microprocessor receives a read command asking for a data within the flash memory module, the microprocessor refers to a status of a specific logical address group corresponding the specific logical address to determine if searching the P2L mapping table or not, to obtain a specific physical address corresponding to the specific logical address, wherein the specific physical address is utilized to read the data from the flash memory module.

9. The flash memory controller of claim 8, the logical address group table utilizes a bit to represent the status of the logical address group, wherein the two digit values of the bit are utilized to represent whether there is any logical address of the logical address group recorded in the P2L mapping table.

10. The flash memory controller of claim 8, wherein each of the logical address groups comprises a logical address range and the logical address range is the same as a range of an L2P mapping table utilized by the flash memory module.

11. The flash memory controller of claim 8, wherein when the status of the specific logical address group indicates that any one of the logical addresses in the logical address group is recorded in the P2L mapping table, the microprocessor directly searches the P2L mapping table to determine whether information related to the specific logical address is contained; and when the status of the specific logical address group indicates that no logical address in the logical address group is recorded in the P2L mapping table, the microprocessor obtains a specific physical address corresponding to the specific logical address form a L2P mapping table without searching the P2L mapping table, to read the data from the flash memory module.

12. The flash memory controller of claim 11, wherein the microprocessor reads the logical address from the flash memory module to the L2P mapping table, and searches the specific physical address from the L2P mapping table.

13. The flash memory controller of claim 12, wherein the microprocessor determines whether a buffer memory of a flash memory controller stores the L2P mapping table; and when the buffer memory has the L2P mapping table, the microprocessor searches for the specific physical address directly from the L2P mapping table stored in the buffer memory; and when the buffer memory does not have the L2P mapping table, the microprocessor reads the L2P mapping table from the flash memory module, and searching for the specific physical address from the L2P mapping table.

14. The flash memory controller of claim 8, wherein the microprocessor reads at least a L2P mapping table from the flash memory module, and determines whether to utilize the P2L mapping table to update the L2P mapping table according to the logical address group table.

15. An electronic device comprising:
a flash memory module; and
a flash memory controller, for accessing the flash memory module, and building a P2L mapping table and a logical address group recording table, wherein the P2L mapping table comprises consecutive physical addresses and corresponding logical addresses of the consecutive physical addresses, and the logical address group tablerecords the statuses of a plurality of logical address groups, wherein the status of each logical address group is utilized to represent whether there is any logical address of the logical address group recorded in the P2L mapping table;
wherein when the flash memory controller receives a read command asking for a data within the flash memory module, the flash memory controller refers to a status of a specific logical address group corresponding the specific logical address to determine if searching the P2L mapping table or not, to obtain a specific physical address corresponding to the specific logical address, wherein the specific physical address is utilized to read the data from the flash memory module.

16. The electronic device of claim 15, the logical address group table utilizes a bit to represent the status of the logical address group, wherein the two digit values of the bit are utilized to represent whether there is any logical address of the logical address group recorded in the P2L mapping table.

17. The electronic device of claim 15, wherein each of the logical address groups comprises a logical address range and the logical address range is the same as a range of an L2P mapping table utilized by the flash memory module.

18. The electronic device of claim 15, wherein when the status of the specific logical address group indicates that any one of the logical addresses in the logical address group is recorded in the P2L mapping table, the flash memory controller directly searches the P2L mapping table to determine whether information related to the specific logical address is contained; and when the status of the specific logical address group indicates that no logical address in the logical address group is recorded in the P2L mapping table, the flash memory controller obtains a specific physical address corresponding to the specific logical address form a L2P mapping table without searching the P2L mapping table, to read the data from the flash memory module.

19. The electronic device of claim 18, wherein the flash memory controller reads the logical address from the flash memory module to the L2P mapping table, and searches the specific physical address from the L2P mapping table.

20. The electronic device of claim 19, wherein the flash memory controller determines whether a buffer memory of a flash memory controller stores the L2P mapping table; and when the buffer memory has the L2P mapping table, the flash memory controller searches for the specific physical address directly from the L2P mapping table stored in the buffer memory; and when the buffer memory does not have the L2P mapping table, the flash memory controller reads the L2P mapping table from the flash memory module, and searching for the specific physical address from the L2P mapping table.
